(19) United States
(12) Patent Application Publication
(10) Pub. No.: US 2005/0158950 A1
(43) Pub. Date: Jul. 21, 2005

(54) Non-volatile memory cell comprising a dielectric layer and a phase change material in series

(75) Inventors: Roy E. Scheuerlein, Cupertino, CA (US); S. Brad Herner, San Jose, CA (US)

Correspondence Address: MATRIX SEMICONDUCTOR, INC., 3230 SCOTT BOULEVARD, SANTA CLARA, CA, 95054, US

(73) Assignee: Matrix Semiconductor, Inc., Santa Clara, CA (US)

(21) Appl. No.: 11/040,255

(22) Filed: Jan. 19, 2005

Related U.S. Application Data
(63) Continuation-in-part of application No. 10/855,784, filed on May 26, 2004.
Application No. 10/855,784 is a continuation of application No. 10/326,470, filed on Dec. 19, 2002, now abandoned.

(51) Int. Cl. H01L 21/336

(52) U.S. Cl. 438/257

(57) ABSTRACT

The invention provides for a nonvolatile memory cell comprising a dielectric material in series with a phase change material, such as a chalcogenide. Phase change is achieved in chalcogenide memories by thermal means. Concentrating thermal energy in a relatively small volume assists this phase change. By applying high voltage across a dielectric layer, dielectric breakdown occurs, forming a low-resistance rupture region traversing the dielectric layer. This rupture region can serve to concentrate thermal energy in a phase-change memory cell. In a preferred embodiment, such a cell can be used in a monolithic three dimensional memory array.

### RELATED APPLICATIONS

This application is a continuation-in-part of Herner et al., U.S. patent application Ser. No. 10/855,784, “An Improved Method for Making High-Density Nonvolatile Memory,” filed May 26, 2004; which is a continuation of Herner et al., U.S. patent application Ser. No. 10/326,470, “An Improved Method for Making High-Density Nonvolatile Memory,” filed Dec. 19, 2002 (since abandoned) and hereinafter the '470 application, both assigned to the assignee of the present invention and hereby incorporated by reference in their entirety.

This application is related to Scheuerlein, U.S. application Ser. No. ______, “Structure and Method for Biasing Phase Change Memory Array for Reliable Writing,” (attorney docket number MA-132); to Scheuerlein, U.S. application Ser. No. ______ “A Non-Volatile Phase Change Memory Cell Having a Reduced Thermal Contact Area,” (attorney docket number MA-133); and to Scheuerlein, U.S. application Ser. No. ______, “A Write-Once Nonvolatile Phase Change Memory Array,” (attorney docket number MA-134); all filed on even date herewith and hereby incorporated by reference.

### BACKGROUND OF THE INVENTION

The invention relates to a nonvolatile memory cell comprising a dielectric layer and a phase-change element in series.

Phase-change materials such as chalcogenides have been used in nonvolatile memories. Such materials can exist in one of two or more stable states, for example a high-resistance and a low-resistance state. In chalcogenides, the high-resistance state corresponds to an amorphous state, while the low-resistance state corresponds to a more ordered crystalline state. The conversion between states is generally achieved thermally.

Conversion from one phase to another is achieved most effectively if the thermal energy is focused into a relatively small area. Some prior art devices have tried to focus thermal energy by forming a very small contact area using photolithography. The limits of photolithography, however, restrict the usefulness of this approach. A need exists, therefore, for a method to concentrate heat in a phase change memory in a volume smaller than that easily achievable using photolithography.

### SUMMARY OF THE INVENTION

The present invention is defined by the following claims, and nothing in this section should be taken as a limitation on those claims. In general, the invention is directed to a nonvolatile memory cell comprising a phase change element and a dielectric layer in series.

A first aspect of the invention provides for a method for forming and programming a nonvolatile memory cell, the method comprising forming a layer of phase change material; forming a dielectric layer in thermal contact with the layer of phase change material; and forming a low-resistance rupture region through the dielectric layer.

Another aspect of the invention provides for a nonvolatile memory cell comprising: a bottom conductor; a top conductor; a dielectric layer having a low-resistance ruptured region therethrough; and a layer of phase change material, wherein the layer of phase change material is in thermal contact with the dielectric layer, wherein the dielectric layer and the layer of phase change material are disposed between the bottom conductor and the top conductor, and wherein the dielectric layer and the layer of phase change material are part of the memory cell.

A preferred embodiment of the invention provides for a nonvolatile memory array comprising a plurality of substantially parallel, substantially coplanar first conductors formed at a first height above a substrate; a plurality of substantially parallel, substantially coplanar second conductors formed at a second height, the second height above the first height; a plurality of first phase change elements disposed between the first and second conductors; a plurality of first dielectric layers, each first dielectric layer in thermal contact with one of the plurality of first phase change elements, each of the first dielectric layers having a high-conductance ruptured region therethrough; and a plurality of first memory cells, wherein each memory cell of the plurality comprises a) one of the first phase change elements, b) one of the first dielectric layers, c) a portion of one of the first conductors, and d) a portion of one of the second conductors.

Another aspect of the invention provides for a monolithic three dimensional memory array comprising: a) a first memory level, the first memory level comprising: i) a plurality of substantially coplanar first conductors; ii) a plurality of substantially coplanar second conductors above the first conductors; iii) a plurality of first dielectric regions, each having a low-resistance ruptured region therethrough; iv) a plurality of first phase change elements, each phase change element in series with the ruptured region of one of the first dielectric regions, wherein each of the first dielectric regions and each of the first phase change elements are disposed between one of the first conductors and one of the second conductors; and b) a second memory level monolithically formed above the first memory level.

Another preferred embodiment of the invention provides for a method for forming and programming a plurality of memory cells, the method comprising: forming a plurality of substantially coplanar first conductors above a substrate; forming a plurality of substantially coplanar second conductors above the first conductors; forming a plurality of first dielectric regions; forming a plurality of first phase change elements, each in thermal contact with one of the first dielectric regions, wherein each of the first phase change elements and each of first dielectric regions are disposed between one of the first conductors and one of the second conductors; forming a low-resistance ruptured region through each of the first dielectric regions; and causing a phase change of any of the phase change elements by flowing a current through the low-resistance ruptured region of one of the first dielectric regions.

Yet another aspect of the invention provides for a method for forming and programming a nonvolatile memory cell, the method comprising: forming a layer of phase change material; forming a heater layer; forming a dielectric layer disposed between the layer of phase change material and the heater layer and in contact with both; and forming a low-resistance rupture region through the dielectric layer.

A related aspect of the invention provides for a nonvolatile memory cell comprising: a bottom conductor; a top conductor; a dielectric layer having a low-resistance ruptured region therethrough; a layer of phase change material; and a heater layer; wherein the dielectric layer is disposed between and in contact with the layer of phase change material and the heater layer, and wherein the dielectric layer and the layer of phase change material are disposed between the bottom conductor and the top conductor, and wherein the dielectric layer and the layer of phase change material are part of the memory cell.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIG. 1 is a cross-sectional view of a portion of a prior art memory cell.

FIG. 2 is a perspective view of a nonvolatile memory cell formed according to an embodiment of the present invention.

FIGS. 3a-3c are cross-sectional views illustrating stages of formation of a memory array formed according to a preferred embodiment of the present invention.

FIG. 4 is a cross-sectional view of an exemplary diode that may be present in a memory cell formed according to the present invention.

FIG. 5a is a perspective view of stacked memory levels with conductors shared between adjacent memory levels according to a preferred embodiment of the present invention. FIG. 5b is a cross-sectional view of several stacked memory levels of such an array.

FIG. 6a is a perspective view of stacked memory levels with conductors not shared between adjacent memory levels according to a preferred embodiment of the present invention. FIG. 6b is a cross-sectional view of several stacked memory levels of such an array.

FIG. 7a is a perspective view of stacked memory levels with conductors shared between some adjacent memory levels and not shared between other adjacent memory levels according to a preferred embodiment of the present invention. FIG. 7b is a cross-sectional view of such an array.

FIG. 8 is a perspective view of a memory cell according to an embodiment of the present invention in which the cell does not include an isolation device.

FIGS. 9a and 9b are cross-sectional views showing formation of memory cells and a contact according to an embodiment of the present invention in which the cell does not include an isolation device.

### DETAILED DESCRIPTION OF PREFERRED EMBODIMENTS OF THE INVENTION

While all materials can change phase, in this discussion the term “phase change material” will be used to describe a material that changes relatively easily from one stable state to another. The phase change is typically from an amorphous state to a crystalline state (or vice versa), but may be an intermediate change, such as from a less-ordered to a more ordered crystalline state, or vice versa. Chalcogenides are well-known phase change materials.

It is known to use phase change materials, such as chalcogenides, in a nonvolatile memory cell, in which a high-resistance, amorphous state represents one memory state while a low-resistance, crystalline state represents the other memory state, where memory states correspond to a value of 1 or 0. (If intermediate stable states are achieved, more than two memory states can exist for each cell; for simplicity, the examples in this discussion will describe only two memory states.) Chalcogenides are particularly useful examples of phase change materials, but it will be understood that other materials which undergo reliably detectable stable phase changes, such as silicon, can be used instead.

Phase change material is converted from one state to the other by heating to high temperature. To facilitate this conversion, mechanisms have been used to concentrate heat in a relatively small area contacting the phase change material. For example, as shown in FIG. 1, in some prior art devices, the phase change material 6 is formed with a portion having a narrow cross-section contacting a heater element 8. In such a scheme, the achievable reduction in area is dictated by the limits of photolithography; ie the contact can be no smaller than the minimum feature size that can be patterned and etched.

Another approach to this problem appears in Czubatyj et al., U.S. Pat. No. 5,825,046, “Composite memory material comprising a mixture of phase-change memory material and dielectric material,” in which the phase change material is layered or otherwise mixed with dielectric material to form a composite, thus reducing the volume of actual phase change material present.

The present invention takes a different approach, providing a simple, easily manufacturable solution to the problem of focusing thermal energy in a non-volatile memory cell comprising a phase change element.

In aspects of the present invention, a nonvolatile memory cell includes a dielectric layer in series with the phase change material. A voltage is applied across the dielectric layer sufficient to cause dielectric breakdown across the dielectric layer, creating a low-resistance rupture region (or, in some cases, possibly more than one.) The diameter of such a rupture region is very small. A typical rupture region formed by applying a voltage across a silicon dioxide layer about 10 to about 20 angstroms thick sufficient to cause dielectric breakdown, for example, may be about 50 to about 100 angstroms in diameter.

Such a dielectric layer in which a low-resistance rupture region is formed is an example of an antifuse. An antifuse is characterized by the property of being insulating as formed, preventing current flow; then, when exposed to a high voltage, irreversibly changing its character to become conductive (at least in some regions) and allowing the flow of current.

The very narrow rupture region serves to focus the thermal energy into an extremely small volume, aiding conversion of phase change material in series with the dielectric layer having the rupture region. For example, the dielectric layer having the rupture region and the phase change material may be formed in series, interposed between conductors. Other elements may exist in the cell, such as a heater layer and a diode.

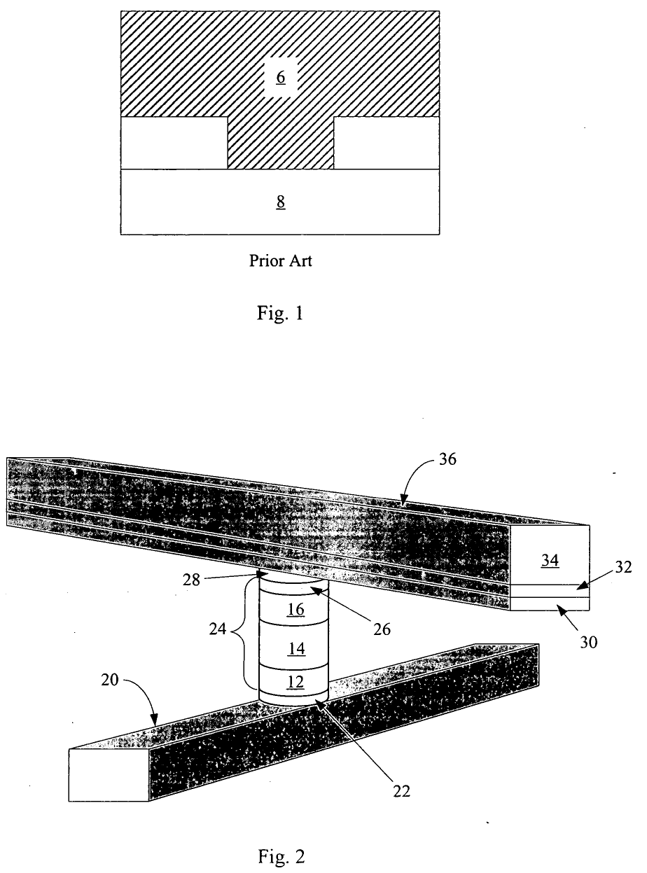

An exemplary nonvolatile memory cell formed according to the present invention is shown in FIG. 2. It will be understood that this cell is just one example of the many forms a nonvolatile memory cell according to the present invention might take.

Bottom conductor 20 is formed of a conductive material, for example a refractory metal or refractory metal compound such as tungsten or titanium tungsten. In this exemplary cell, bottom conductor 20 is in the form of a rail. A barrier layer 22 of, for example, titanium nitride may be used between conductor 20 and polysilicon diode 24. (In this discussion, the term “polysilicon” will be used to describe polycrystalline silicon.) Polysilicon diode 24 may comprise a bottom heavily doped layer 12 of a first conductivity type, a middle lightly doped or intrinsic layer 14, and a top heavily doped layer 16 of a second conductivity type opposite the first conductivity type. A thin low thermal conductivity layer 26 is formed on the diode. This layer acts as a heater. Heater layer 26 can be formed of, for example, cobalt silicide. A layer 28 of dielectric material, for example silicon dioxide, is formed on heater layer 26. In the embodiment shown in FIG. 2, titanium nitride layer 22, diode 24, heater layer 26 and silicon dioxide layer 28 are in the form of a vertically oriented pillar.

A layer 30 of phase change material, in this example a chalcogenide, is formed above silicon dioxide layer 28. Above chalcogenide layer 30 is a layer of a conductive material 34, for example a refractory metal or refractory metal compound such as tungsten or titanium tungsten. A barrier layer 32 of titanium nitride may be disposed between the chalcogenide layer 30 and conductive layer 34. In this embodiment, chalcogenide layer 30, barrier layer 32, and conductive layer 34 are in the form of a rail-shaped top conductor 36. Top conductor 36 is preferably perpendicular to bottom conductor 20.

When this memory cell is initially formed, silicon dioxide layer 28 is intact. After a voltage sufficient to cause dielectric breakdown is applied between bottom conductor 20 and top conductor 36, a low resistance rupture region (not shown) forms traversing silicon dioxide layer 28 from heater layer 26 to chalcogenide layer 30. This low resistance rupture region is a permanent feature. After its formation, when voltage is applied between conductors 20 and 36, this rupture region provides a low-resistance current path through silicon dioxide layer 28.

The cell just described is just one example of the forms that a nonvolatile memory cell formed according to the present invention may take; clearly many other configurations are possible. For example, the memory cell just described includes a non-ohmic conductive element, the diode 24, to serve as an isolation device. A non-ohmic conductive element is characterized by a non-linear current vs. voltage curve. Other non-ohmic elements may be used in place of the diode. For example, a metal-insulator-metal device consists of two metal (or metal-like) layers separated by a very thin insulator layer. When sufficient voltage is applied, charge carriers can tunnel across the insulator layer, but do not permanently damage it, as in an antifuse. In alternative embodiments of the present invention, the diode 24 of the memory cell of FIG. 2 could be replaced with a MIM device.

Other suitable materials can be used for any of the elements of the cell just described. For example, titanium nitride replace can cobalt silicide in heater layer 26. Other suitable materials for heater layer 26 would be any conductor having sheet resistance preferably between about 100 kiloOhm/□ and about 1 kiloOhm/□. Other metal silicides can be used, for example, or refractory metal compounds.

A detailed example will be provided describing fabrication of a monolithic three dimensional memory array, the nonvolatile memory cells of the array formed according to one preferred embodiment of the present invention. The example array will include a diode, as in the memory cell just described, though other configurations could be used instead; for example some other non-ohmic conductive element, such as a MIM, could be substituted for the diode. For completeness, specific process conditions, dimensions, methods, and materials will be provided. It will be understood, however, that such details are not intended to be limiting, and that many of these details can be modified, omitted or augmented while the results still fall within the scope of the invention.

Fabrication

Fabrication of a single memory level will be described in detail. Additional memory levels can be stacked, each monolithically formed above the one below it.

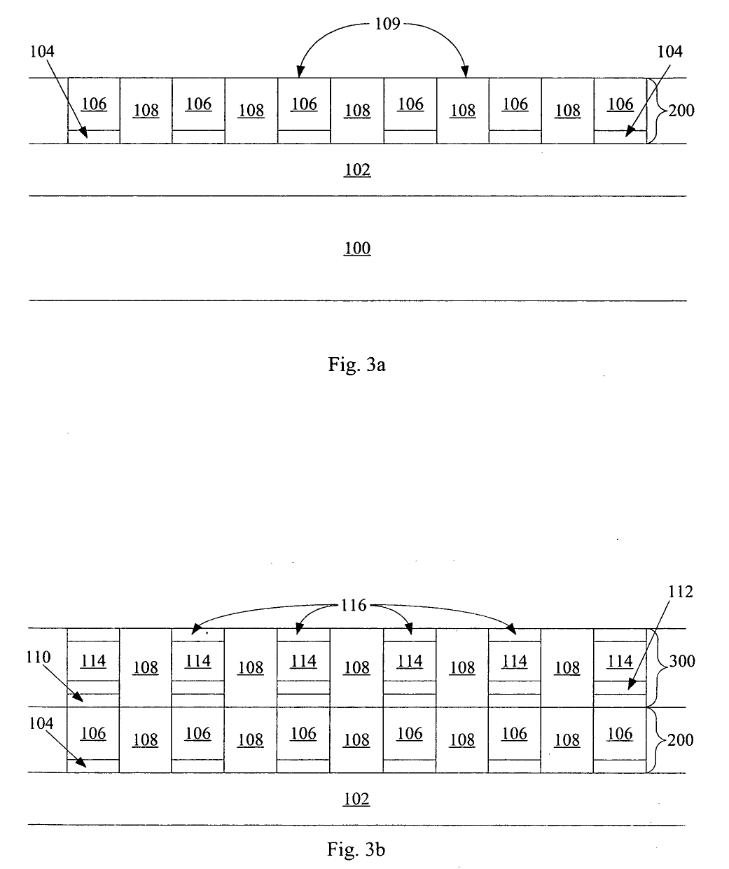

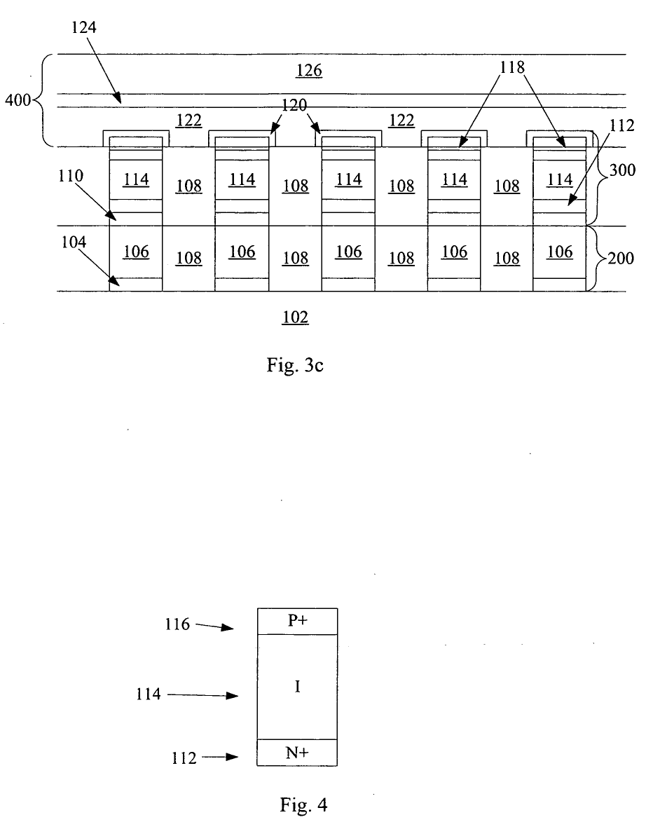

Turning to FIG. 3a, formation of the memory begins with a substrate 100. This substrate 100 can be any semiconducting substrate as known in the art, such as monocrystalline silicon, IV-IV compounds like silicon-germanium or silicon-germanium-carbon, III-V compounds, II-VII compounds, epitaxial layers over such substrates, or any other semiconducting material. The substrate may include integrated circuits fabricated therein.

An insulating layer 102 is formed over substrate 100. The insulating layer 102 can be silicon oxide, silicon nitride, high-dielectric film, Si—C—O—H film, or any other suitable insulating material.

The first conductors 200 are formed over the substrate and insulator. An adhesion layer 104 may be included between the insulating layer 102 and the conducting layer 106 to help the conducting layer 106 adhere. Preferred materials for the adhesion layer 104 are tantalum nitride, tungsten nitride, titanium tungsten, tungsten, titanium nitride, or combinations of these materials. If the overlying conducting layer is tungsten, titanium nitride is preferred as adhesion layer 104.

The next layer to be deposited is conducting layer 106. Conducting layer 106 can comprise any conducting material known in the art, including tantalum, titanium, tungsten, copper, cobalt, or alloys thereof. Titanium nitride may be used.

Once all the layers that will form the conductor rails have been deposited, the layers will be patterned and etched using any suitable masking and etching process to form substantially parallel, substantially coplanar conductors 200, shown in FIG. 3a in cross-section. In one embodiment, photoresist is deposited, patterned by photolithography and the layers etched, and then the photoresist removed using standard process techniques. Conductors 200 could be formed by a Damascene method instead.

Next a dielectric material 108 is deposited over and between conductor rails 200. Dielectric material 108 can be any known electrically insulating material, such as silicon oxide, silicon nitride, or silicon oxynitride. In a preferred embodiment, silicon oxide is used as dielectric material 108.

Finally, excess dielectric material 108 on top of conductor rails 200 is removed, exposing the tops of conductor rails 200 separated by dielectric material 108, and leaving a substantially planar surface 109. The resulting structure is shown in FIG. 3a. This removal of dielectric overfill to form planar surface 109 can be performed by any process known in the art, such as chemical mechanical planarization (CMP) or etchback. At this stage, a plurality of substantially parallel first conductors have been formed at a first height above substrate 100.

Next, turning to FIG. 3b, vertical pillars will be formed above completed conductor rails 200. (To save space substrate 100 is not shown in FIG. 3b; its presence will be assumed.) Preferably a barrier layer 110 is deposited as the first layer after planarization of the conductor rails. Any suitable material can be used in the barrier layer, including tungsten nitride, tantalum nitride, titanium nitride, or combinations of these materials. In a preferred embodiment, titanium nitride is used as the barrier layer. Where the barrier layer is titanium nitride, it can be deposited in the same manner as the adhesion layer described earlier.

Next semiconductor material that will be patterned into pillars is deposited. The semiconductor material can be silicon, silicon-germanium, silicon-germanium-carbon, germanium, or other suitable semiconductors or compounds. One of the most commonly used chalcogenide materials is Ge₂Sb₂Te₅, which has a melting temperature of 610 degrees C. Germanium and silicon-germanium alloys crystallize at lower temperatures than silicon, and may be useful in reducing the temperatures required to fabricate the structure to be described. For simplicity, this description will refer to the semiconductor material as silicon, but it will be understood that the skilled practitioner may select any of these other suitable materials instead.

In preferred embodiments, the pillar comprises a semiconductor junction diode. Turning to FIG. 4, a preferred junction diode has a bottom heavily doped region 112, intrinsic region 114, and top heavily doped region 116. The conductivity type of bottom region 112 and top region 116 are opposite: Either region 112 is p-type while region 116 is n-type, or region 112 is n-type while region 116 is p-type. Middle region 114 is intrinsic, or not intentionally doped, though in some embodiments it may be lightly doped. An undoped region will never be perfectly electrically neutral, and will always have defects or contaminants that cause it to behave as if slightly n-doped or p-doped. Such a diode can be considered a p-i-n diode.

In FIG. 4, and in the exemplary array, bottom region 112 will be n-type while top region 116 is p-type. It will understood that these conductivity types could be reversed. To form the diode of FIG. 4, bottom heavily doped region 112 can be formed by any deposition and doping method known in the art. The silicon can be deposited and then doped, but is preferably doped in situ by flowing a donor gas providing n-type dopant atoms, for example phosphorus, during deposition of the silicon.

The next layer 114 will be intrinsic undoped silicon. This layer can formed by any deposition method known in the art. The thickness of the intrinsic silicon layer can range from about 1000 to about 4000 angstroms, preferably about 2500 angstroms. In one embodiment, silicon is deposited without intentional doping, yet has defects which render it slightly n-type.

Above this is a layer 116 of heavily doped p-type silicon. This layer is preferably deposited undoped, and will be doped by ion implantation in a later step. The thickness of heavily doped p-type silicon region 116 can range from about 100 to about 2000 angstroms, preferably about 800 angstroms. Note this is the thickness as-deposited. Some portion of the top of this layer will be consumed in a subsequent CMP or etchback step, and will thus be thinner in the finished device.

Returning to FIG. 3b, semiconductor layers 116, 114 and 112 just deposited, along with underlying barrier layer 110, will be patterned and etched to form pillars 300. Pillars 300 should have about the same pitch and about the same width as conductors 200 below, such that each pillar 300 is formed on top of a conductor 200. Some misalignment can be tolerated. To summarize, the diodes are formed by depositing a semiconductor layer stack and patterning and etching the layer stack to form a pillar.

The pillars 300 can be formed using any suitable masking and etching process. For example, photoresist can be deposited, patterned using standard photolithography techniques, and etched, then the photoresist removed. Alternatively, a hard mask of some other material, for example silicon dioxide, can be formed on top of the semiconductor layer stack, with bottom antireflective coating (BARC) on top, then patterned and etched. Similarly, dielectric antireflective coating (DARC) can be used as a hard mask.

The photolithography techniques described in Chen, U.S. application Ser. No. 10/728,436, “Photomask Features with Interior Nonprinting Window Using Alternating Phase Shifting,” filed Dec. 5, 2003; or Chen, U.S. application Ser. No. 10/815,312, Photomask Features with Chromeless Nonprinting Phase Shifting Window,” filed Apr. 1, 2004, both owned by the assignee of the present invention and hereby incorporated by reference, can advantageously be used to perform any photolithography step used in formation of a memory array according to the present invention.

Dielectric material 108 is deposited over and between the semiconductor pillars 300, filling the gaps between them. Dielectric material 108 can be any known electrically insulating material, such as silicon oxide, silicon nitride, or silicon oxynitride. In a preferred embodiment, silicon dioxide is used as the insulating material.

Next the dielectric material on top of the pillars 300 is removed, exposing the tops of pillars 300 separated by dielectric material 108, and leaving a substantially planar surface. This removal of dielectric overfill can be performed by any process known in the art, such as CMP or etchback. After CMP or etchback, ion implantation is performed, heavily doping top region 116 of the diode with a p-type dopant, for example boron. The resulting structure is shown in FIG. 3b.

Turning to FIG. 3c, in preferred embodiments a thin layer of about 20 to about 100 angstroms of cobalt (not shown) is deposited on the dielectric 108 and exposed pillars 300. Cobalt can be deposited by any conventional method, for example by sputtering. Other metals that form metal silicides can be used in place of cobalt, including chromium, nickel, platinum, niobium, palladium, tantalum, or titanium. For simplicity, this description will detail the use of cobalt, but it will be understood that any of these other metals can be substituted as appropriate.

Optionally, a capping layer of about 200 angstroms, preferably of titanium or titanium nitride, is deposited on the cobalt (not shown.) The titanium or titanium nitride cap assists in the subsequent conversion of the cobalt layer to cobalt silicide.

Turning to FIG. 3c, an anneal is performed at a suitable temperature to react the cobalt with the polysilicon of the exposed diodes to form cobalt silicide 118 on the diodes only; no silicide is formed where the cobalt overlies oxide fill 108. For example, the anneal may be performed in a rapid thermal annealing system at about 400 to about 700 degrees C. for about 20 to about 100 seconds, preferably at about 500 degrees C. for about 30 seconds. The capping layer and unreacted portions of the cobalt are removed by a selective etch. Any etching medium which selectively etches the capping layer and the unreacted cobalt while leaving cobalt silicide may be used. Preferably, selective wet etching is used.

If desired, a second anneal may be performed to homogenize the cobalt silicide 118 to CoSi₂. This second anneal can be performed at any time after the first. In a multi-level memory array, preferably a single anneal is performed after all of the memory levels are constructed to homogenize the cobalt silicide. Alternatively, the second anneal can be combined with antifuse growth. Layer 118 will serve as a heater layer, heating a portion of a phase change layer (still to be formed) to cause it to undergo a desired phase change.

Next a dielectric layer 120, which is preferably an oxide, nitride, or oxynitride layer, is formed on cobalt suicide 118. In preferred embodiments, as shown, silicon oxide is grown by exposing the silicide layer 118 to an oxygen atmosphere in a rapid thermal annealing system, preferably at about 670 to about 750 degrees C. for about 20 to about 60 seconds. Note that some but not all of the top heavily doped region 116 has been consumed by the silicide reaction. If desired, dielectric layer 120 could have been deposited instead, or chemically grown. Other materials could be used, for example aluminum oxide. Some of these other methods lend the advantage of lower temperature processing.

If aluminum oxide is used, a layer about 20 angstroms thick may be deposited by DC-magnetron sputtering in a vacuum system and plasma oxidizing in an O₂ atmosphere at 100 mTorr for two to six minutes. The resistance of the resulting aluminum oxide layer is about 10 megaOhms/micron². Alternatively, such a layer could be formed by any other conventional method.

Next layer 122 of a phase change material, preferably a chalcogenide material, is formed on dielectric layers 120 and intervening dielectric material 108. Layer 122 can be any chalcogenide material, for example any suitable compound of germanium (Ge), antimony (Sb) and tellurium (Te); such a compound is referred to as a GST material. A GST material that may advantageously be employed in memory applications, as in memory cells formed according to the present invention, is Ge₂Sb₂Te₅. Phase change layer 122 can be formed by any conventional method.

In preferred embodiments a thin barrier layer 124 is formed on phase change layer 122. Barrier layer 124 provides a barrier between phase change layer 122 and conductive layer 126. Conductive layer 126 is formed of a conductive material, for example tungsten.

Phase change material layer 122, barrier layer 124, and conductive layer 126 are then patterned and etched using any suitable masking and etching process to form substantially parallel, substantially coplanar conductors 400, shown in FIG. 3c extending left-to-right across the page. In one embodiment, photoresist is deposited, patterned by photolithography and the layers etched, and then the photoresist removed using standard process techniques.

Next a dielectric material (not shown) is deposited over and between conductor rails 400. The dielectric material can be any known electrically insulating material, such as silicon oxide, silicon nitride, or silicon oxynitride. In a preferred embodiment, silicon oxide is used as this dielectric material.

While the structure of the array just described diverges in some important ways from the structure of the array of Herner et al., wherever they are the same, the fabrication methods of Herner et al. can be used. For clarity, not all of the fabrication details of Herner et al. were included in this description, but no part of that description is intended to be excluded. Similarly, some methods of Petti et al., U.S. patent application Ser. No. 10/728,230, “Semiconductor Device Including Junction Diode Contacting Contact-Antifuse Unit Comprising Silicide,” filed Dec. 3, 2003, owned by the assignee of the present invention and hereby incorporated by reference, may be useful in forming embodiments of the present invention, and no teaching of that application is intended to be excluded.

Each memory cell just created is a nonvolatile memory cell comprising a bottom conductor; a top conductor; a dielectric layer having a low-resistance ruptured region therethrough; and a layer of phase change material, wherein the layer of phase change material is in thermal contact with the dielectric layer, wherein the dielectric layer and the layer of phase change material are disposed between the bottom conductor and the top conductor, and wherein the dielectric layer and the layer of phase change material are part of the memory cell. A layer or element is considered to be in thermal contact with phase change material when thermal events within that layer or element are capable of thermally affecting the phase change material sufficient to cause it to detectably change phase.

The structure just described is a nonvolatile memory array comprising a plurality of substantially parallel, substantially coplanar first conductors formed at a first height above a substrate; a plurality of substantially parallel, substantially coplanar second conductors formed at a second height, the second height above the first height; a plurality of first phase change elements disposed between the first and second conductors; a plurality of first dielectric layers, each first dielectric layer in thermal contact with one of the plurality of first phase change elements, each of the first dielectric layers having a high-conductance ruptured region therethrough; and a plurality of first memory cells, wherein each memory cell of the plurality comprises a) one of the first phase change elements, b) one of the first dielectric layers, c) a portion of one of the first conductors, and d) a portion of one of the second conductors.

This structure, shown in FIG. 3c, is a first memory level. Additional memory levels can be monolithically formed above this memory level to form a monolithic three dimensional memory array. A monolithic three dimensional memory array is one in which multiple memory levels are formed above a single substrate, such as a wafer, with no intervening substrates. In contrast, stacked memories have been constructed by forming memory levels on separate substrates and adhering the memory levels atop each other, as in Leedy, U.S. Pat. No. 5,915,167, “Three dimensional structure memory.”The substrates may be thinned or removed from the memory levels before bonding, but as the memory levels are initially formed over separate substrates, such memories are not true monolithic three dimensional memory arrays.

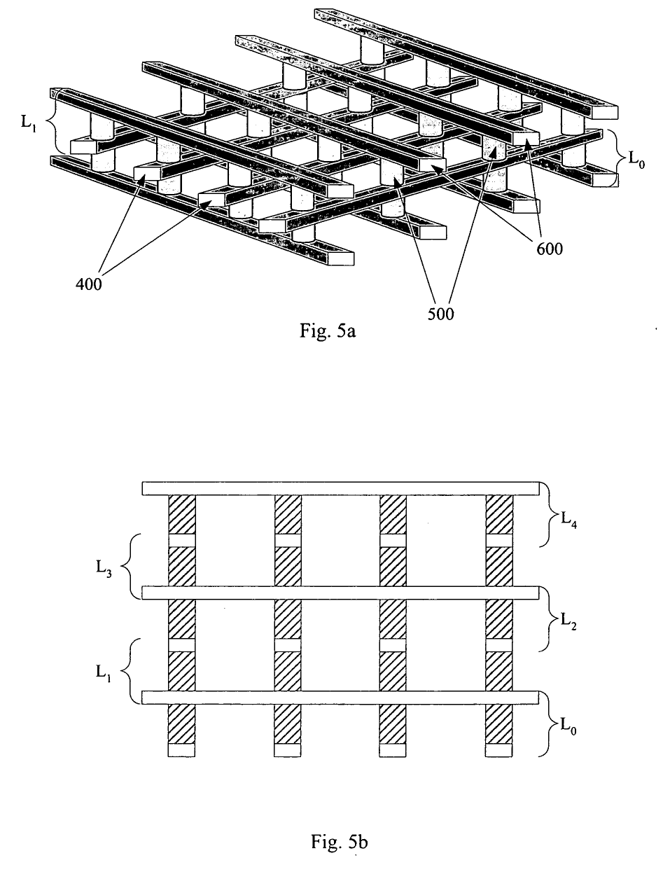

A second memory level can be formed above the first memory level just described. In one configuration, top conductors 400 can be shared between adjacent memory levels. Turning to FIG. 5a, if top conductors 400 are to be shared, after planarization second pillars 500 are formed in the same manner as were the first pillars 300, each on one of the conductors 400. A third plurality of substantially parallel, substantially coplanar conductors 600, preferably substantially perpendicular to second conductors 400, are formed above second pillars 500. It will be seen that conductors 400 belong to both memory level L₀ and to memory level L₁. In this case, in preferred embodiments, the p-i-n diodes in the second pillars 500 may be upside down relative to the p-i-n diodes of first pillars 300; eg if, in first pillars 300, the bottom heavily doped region is n-type and the top heavily doped region is p-type, then in second pillars 500 the bottom heavily doped region may be p-type while the top heavily doped region is n-type.

FIG. 5b shows five memory levels in cross section, illustrating how this scheme can be extended for several stacked levels. One plurality of conductors is shared between L₀ and L₁, a different plurality of conductors is shared between L₁ and L₂, etc.

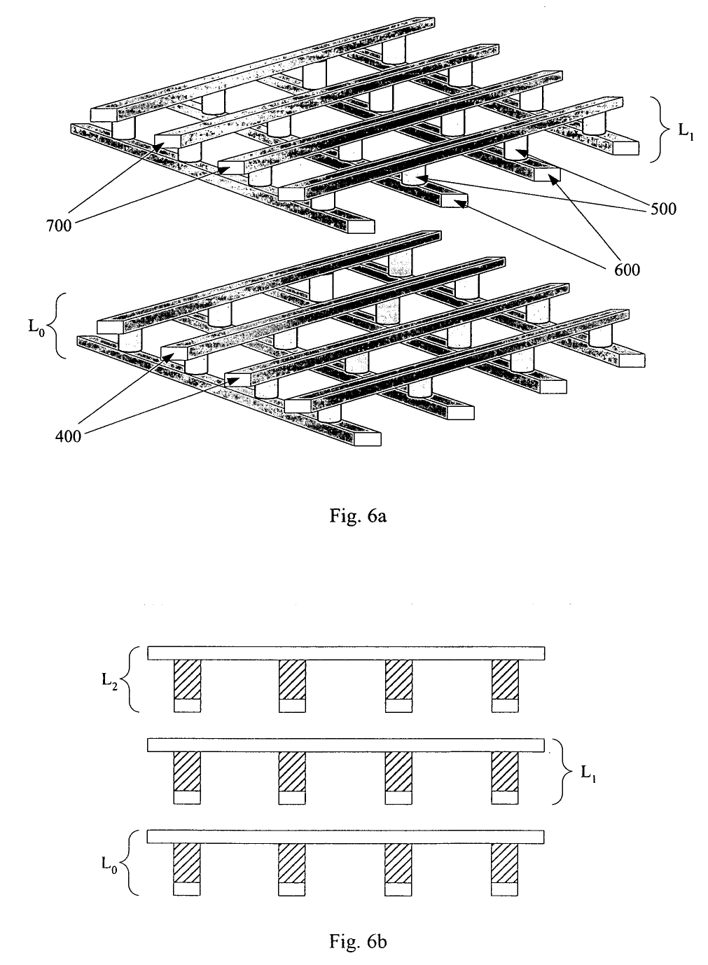

Alternatively, turning to FIG. 6a, an interlevel dielectric (not shown) can be formed between adjacent memory levels. In this case third conductors 600 are formed above the interlevel dielectric, second pillars 500 formed above third conductors 600, and fourth conductors 700 formed above second pillars 500. Conductors 400 belong to memory level L₀ only, while conductors 600 and 700 belong to memory level L₁. No conductors are shared between memory levels. FIG. 6b shows a cross-sectional view of an array in which this scheme is extended for three memory levels. No conductors are shared between memory levels L₀ and L₁, or between memory levels L₁ and L₂. If desired, adjacent memory levels sharing conductors and adjacent memory levels not sharing conductors can be stacked in the same monolithic three dimensional memory array.

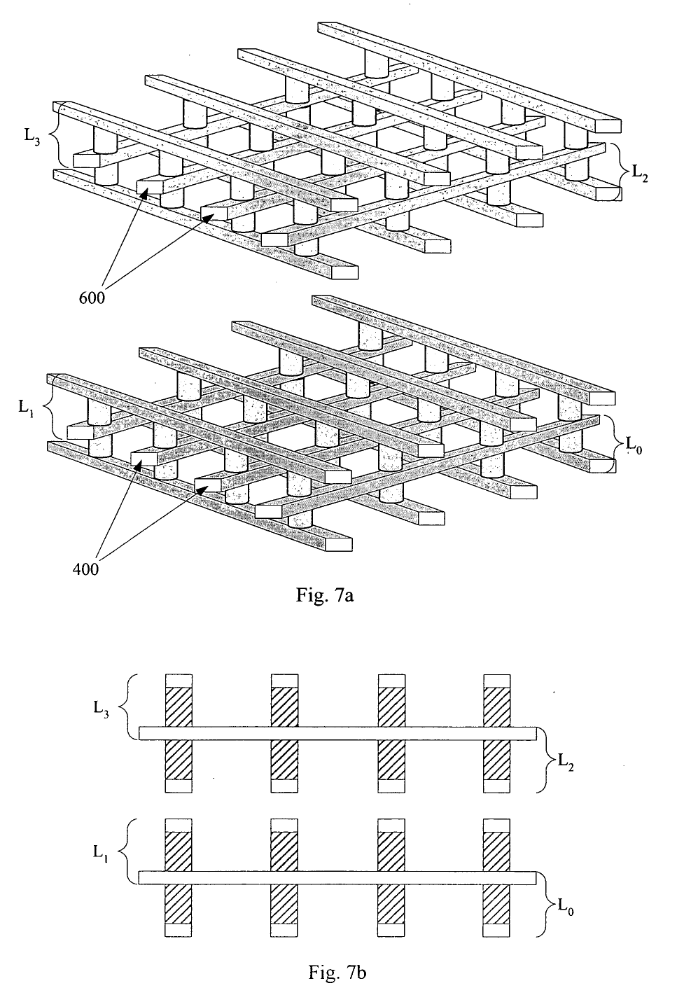

In another embodiment, some conductors may be shared while others are not. FIG. 7a shows a memory array in which conductors 400 are shared between memory levels L₀ and L₁, and conductors 600 are shared between memory levels L₂ and L₃. No conductors are shared between memory levels L₁ and L₂, however. FIG. 7b shows a cross-sectional view of such an array. Other configurations can be envisioned, and fall within the scope of the present invention.

Memory levels need not all be formed having the same style of memory cell. If desired, memory levels using phase change materials can alternate with memory levels using other types of memory cells.

To summarize, the various monolithic three dimensional memory arrays described comprise a) a first memory level, the first memory level comprising: i) a plurality of substantially coplanar first conductors; ii) a plurality of substantially coplanar second conductors above the first conductors; iii) a plurality of first dielectric regions, each having a low-resistance ruptured region therethrough; iv) a plurality of first phase change elements, each phase change element in series with the ruptured region of one of the first dielectric regions, wherein each of the first dielectric regions and each of the first phase change elements are disposed between one of the first conductors and one of the second conductors; and b) a second memory level monolithically formed above the first memory level.

Circuitry and Programming

To convert a chalcogenide in a crystalline, low-resistance state to an amorphous, high-resistance state, the chalcogenide must be brought to a high temperature, for example about 700 degrees C., then allowed to cool quickly. The reverse conversion from an amorphous, high-resistance state to a crystalline, low-resistance state is achieved by heating to a lower temperature, for example about 600 degrees C., then allowing the chalcogenide to cool relatively slowly. Circuit conditions must be carefully controlled in a monolithic three dimensional memory array formed according to the present invention to avoid inadvertent conversion of the chalcogenide of neighboring cells during programming of a cell, or during repeated read events.

Circuit structures and methods suitable for use in three dimensional memory arrays formed according to the present invention are described in Scheuerlein, U.S. patent application Ser. No. 10/403,844, “Word Line Arrangement Having Multi-Layer Word Line Segments for Three-Dimensional Memory Array,” filed Mar. 31, 2003, which is assigned to the assignee of the present invention and is hereby incorporated by reference. Beneficial elements of this arrangement include use of a common word line driver and very long bitlines allowing reduction in overhead circuitry.

Scheuerlein, U.S. patent application Ser. No. ______, (attorney docket no. MA-132), a related application filed on even date herewith, teaches a biasing scheme that could advantageously be used in an array formed according to the present invention. The biasing scheme of this application guarantees that the voltage across unselected and half-selected cells is not sufficient to cause inadvertent conversion of those cells, and allows precise control of the power delivered to the cell to be programmed.

To deliver maximum power to a cell, the resistance of the programmed cell during programming should be about the same as the sum of the resistance of the circuits driving the wordline and bitline of the selected cell. When a low-resistance rupture region is electrically formed by dielectric breakdown across the dielectric layer, the dielectric region is originally high resistance, then drops in resistance as the rupture region forms. As the resistance of the rupture region approaches that of the circuit, the rupture region begins to cool, and will not further increase in size. Thus the formation mechanism of the rupture region tends to cause the rupture region to have about the same resistance as the resistance of the driving circuit. In subsequent programming events, then, the rupture region provides a means to deliver predictable levels of power to the cell. Conventional current limiter circuitry may advantageously be used to control the effective resistance of drivers during programming, as will be well understood by those skilled in the art.

In a memory like the one described in detail earlier, in which feature size ranges from about 0.1 micron down to about 10 nm, the initial resistance of the unruptured antifuse will be very high, between about 1 megaOhm and about 1000 megaOhms. After dielectric breakdown, the resistance of the rupture region will be between about 1 and about 100 kiloOhms.

The resistance of the chalcogenide material, when in the high-resistance state, will range from about 50 kiloOhms to about 2 megaOhms. In the low-resistance state, resistance drops to between about 1 kiloOhm to about 100 kiloOhms; in the example given, resistance is preferably about 3 kiloOhms.

The heater layer similarly has resistance ranging from about 1 kiloOhm to about 100 kiloOhms, in the example given preferably about 2 kiloOhms. Thus, when the rupture region has been formed and the phase change material is in the low-resistance state, the resistances of the heater layer (about 2 kiloOhms), the rupture region of the dielectric (about 1 kiloOhm) and the chalcogenide material (about 1 kiloOhm) are all in approximately the same range.

When in the low-resistance, crystalline state, the resistance of the cell is about 5 kiloOhms, and the power that can be delivered to the cell by providing low resistance driving circuitry is high enough to reach temperatures sufficient to cause phase conversion, even with short pulses. Subsequently the cell is in the high-resistance state, and the maximum power that can be delivered to the circuit is much lower. The driving circuitry is capable of delivering a voltage to the cell above a characteristic threshold voltage in the range of one to two volts which causes current to flow through the high-resistance cell. The power delivered to the cell is limited by the driving circuitry to a level desired for setting the cell in its low-resistance state. The ______ application (attorney docket no. MA-098) filed on even date herewith discusses the relationship between phase and deliverable power in more detail.

A most preferred mode of operating memory cells formed according to the present invention would be to form the memory as described herein, then to form the low-resistance rupture region in the dielectric layer of every cell under controlled conditions as a preconditioning step before the device is delivered to the end user. In some embodiments, the rupture event leaves the memory cell in the high-resistance state. In a preferred embodiment, after low-resistance rupture regions are formed in every cell, the cells are all converted to the crystalline, low-resistance state, final testing of the device is performed, and the memory is ready for use. Many other modes of use are possible, however. For example, the memory can be delivered to the end user with the dielectric antifuses intact, and the rupture event could double as a programming event. The initial state of cells could be either low-resistance or high-resistance.

What has just been described is a method for forming and programming a nonvolatile memory cell, the method comprising forming a layer of phase change material; forming a dielectric layer in thermal contact with the layer of phase change material; and forming a low-resistance rupture region through the dielectric layer. The cell can then be programmed wherein, during programming, a programming current flows through the low-resistance rupture region. Programming the cell changes it from the first state (low- or high-resistance) to a second state (high- or low-resistance). The cell can subsequently be “erased”, returning it to the first state.

In the exemplary cell shown in FIG. 2, during programming, the programming current flows between conductive layer 20 and conductive layer 34, going through diode 24 and the low-resistance rupture region of dielectric layer 26; thus diode 24 and dielectric layer 26 are in series. As described, diode 24 can be replaced with a MIM or with some other non-ohmic conductive element.

After the rupture region is formed in a cell, the diode is in electrical contact with the phase change material, though it may not be in physical contact. One layer is in electrical contact with another when no dielectric layer sufficient to impede current flow is disposed between them.

It will be understood, of course, that many variations on the cell of FIG. 2 are possible. The dielectric layer, phase change layer, and heater layer need not appear in precisely the same orientation or order shown in FIG. 2. The dielectric layer could be below the diode rather than above, for example, as could the phase change material. In preferred embodiments, the phase change layer 30 and the heater layer 26 are on opposite sides of dielectric layer 28. Such a cell can be formed by a method comprising forming a layer of phase change material; forming a heater layer; forming a dielectric layer disposed between the layer of phase change material and the heater layer and in contact with both; and forming a low-resistance rupture region through the dielectric layer.

The memory cell of FIG. 2, for example, comprises a bottom conductor; a top conductor; a dielectric layer having a low-resistance ruptured region therethrough; a layer of phase change material; and a heater layer; wherein the dielectric layer is disposed between and in contact with the layer of phase change material and the heater layer, and wherein the dielectric layer and the layer of phase change material are disposed between the bottom conductor and the top conductor, and wherein the dielectric layer and the layer of phase change material are part of the memory cell.

In other embodiments, though, the dielectric layer, heater layer, and phase change layer may be arranged in a different order.

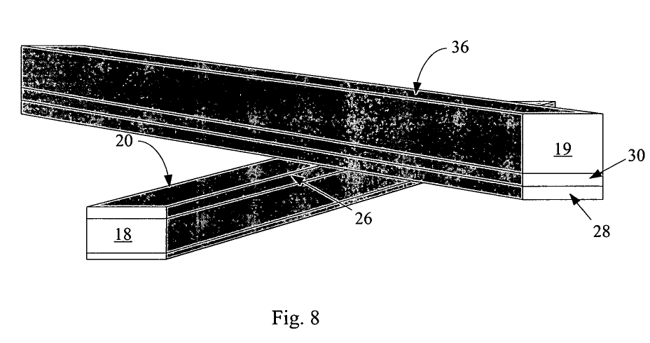

Alternatively, in smaller arrays where isolation of cells (which serves to reduce leakage paths) is not of concern, the cell may have no isolation device in series with the antifuse and the phase change material. One example of such a cell is shown in FIG. 8. Bottom rail 20 is formed of conductive layer 18, which comprises a conductive material such as tungsten, and heater layer 26 which is formed of, for example, titanium nitride or any other suitable material as described in other embodiments. Dielectric layer 28 can be any deposited dielectric, for example aluminum oxide. Phase change layer 30 is, for example, a chalcogenide, or GST material. Above phase change layer 30 in top conductor 36 is conductive layer 19 of any suitable conductive material, such as tungsten. Bottom conductor 20 and top conductor 36 are patterned and etched using any conventional method. If desired, the locations of phase change layer 30 and heater layer 26 could be reversed.

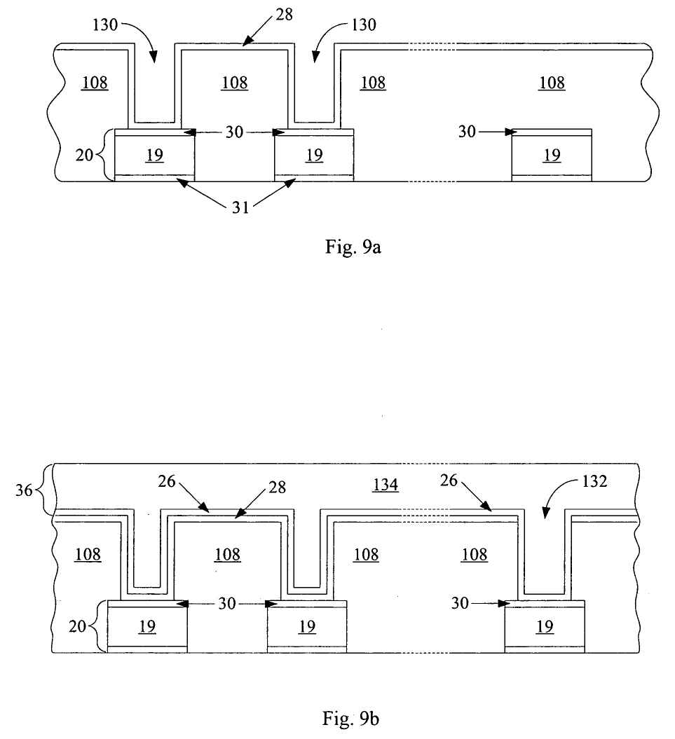

Formation of another example of such an array in which memory cells have no isolation device such as a diode or MIM is illustrated in FIGS. 9a and 9b. In this example, the bottom rails 20 are formed of a conductive material 19 such as tungsten and a layer 30 of a phase change material, for example a chalcogenide. A barrier layer 31 may be included. After bottom rails 20 have been etched, a dielectric material 108 is deposited over and between bottom rails 20. The surface is planarized, for example by CMP. This CMP step does not expose rails 20, and they remain covered with dielectric material 108. A hole 130 is etched through dielectric material 108 in the array at each location where a cell is to be formed. Thin dielectric layer 28, formed of, for example, a nitride, oxide, or oxynitride, is deposited, filling etched hole 130. If the deposited dielectric material deposits on sidewalls, it will coat the walls and the bottom of the etched hole, but only coverage at the bottom of the etched hole is important for device performance.

Next, the etched holes are covered with photoresist. In a second pattern and etch step, holes 132 are etched for contacts outside of the array, shown in 9b. Photoresist is removed and a heater layer 26, for example of titanium nitride, is deposited to line both holes 130 in the array and contact holes 132. A conductive material, for example tungsten fills the holes and forms a conductive layer 134. Conductive layer 134 and heater layer 26 are patterned and etched to form top rails 36, preferably extending perpendicular to bottom rails 20. It will be seen that dielectric layer 28 separates phase change layer 30 and heater layer 26 only in the memory cells, not in the contacts.

Monolithic three dimensional memory arrays are described in Johnson et al., U.S. Pat. No. 6,034,882, “Vertically stacked field programmable nonvolatile memory and method of fabrication”; Johnson, U.S. Pat. No. 6,525,953, “Vertically stacked field programmable nonvolatile memory and method of fabrication”; Knall et al., U.S. Pat. No. 6,420,215, “Three Dimensional Memory Array and Method of Fabrication”; and Vyvoda et al., U.S. patent application Ser. No. 10/185,507, “Electrically Isolated Pillars in Active Devices,” filed Jun. 27, 2002; U.S. patent application Ser. No. 10/185,508, “Three Dimensional Memory,” filed Jun. 27, 2002, all assigned to the assignee of the present invention and all hereby incorporated by reference. Any of these various monolithic three dimensional memory arrays can be modified by the methods of the present invention to form nonvolatile memories having a dielectric layer in series with a phase change material.

The present invention has been described herein in the context of a monolithic three dimensional memory array formed above a substrate. Such an array comprises at least a first memory level formed at a first height above the substrate and a second memory level formed at a second height different from the first height. Three, four, eight, or indeed any number of memory levels can be formed above the substrate in such a multilevel array. Alternatively, a memory array comprising memory cells formed according to the present invention need not be formed in a three dimensional array, and could be a more conventional two dimensional array formed without stacking.

Detailed methods of fabrication have been described herein, but any other methods that form similar structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

1. A method for forming and programming a nonvolatile memory cell, the method comprising:
forming a layer of phase change material;
forming a dielectric layer in thermal contact with the layer of phase change material; and
forming a low-resistance rupture region through the dielectric layer.

2. The method of claim 1 wherein the step of forming a low-resistance rupture region through the dielectric layer comprises applying a breakdown voltage across the dielectric layer sufficient to cause dielectric breakdown of the dielectric layer.

3. The method of claim 1 further comprising programming the memory cell wherein, during programming, a programming current flows through the low-resistance rupture region.

4. The method of claim 3 wherein the step of programming the memory cell comprises converting the phase change material from a first state to a second state.

5. The method of claim 4 wherein the first state is a low-resistance state and the second state is a high-resistance state.

6. The method of claim 4 wherein the first state is a high-resistance state and the second state is a low-resistance state.

7. The method of claim 4 wherein, after programming, the memory cell can be returned to the first state.

8. The method of claim 3 further comprising forming a non-ohmic conductive element, wherein, during the programming step, the programming current flows through the non-ohmic conductive element.

9. The method of claim 8 wherein the non-ohmic conductive element is a diode.

10. The method of claim 9 wherein the diode is in electrical contact with the layer of phase change material.

11. The method of claim 10 wherein a conductive barrier layer is between the diode and the layer of phase change material.

12. The method of claim 9 wherein the diode is in electrical contact with the dielectric layer.

13. The method of claim 9 wherein the diode is a semiconductor junction diode.

14. The method of claim 13 wherein the semiconductor junction diode is a vertically oriented pillar.

15. The method of claim 14 wherein the step of forming the diode comprises:
depositing a semiconductor layer stack; and
patterning and etching the layer stack to form the pillar.

16. The method of claim 8 wherein the non-ohmic conductive element is a MIM.

17. The method of claim 1 wherein the dielectric layer comprises an oxide layer or a nitride layer.

18. The method of claim 1 wherein the phase change material comprises a chalcogenide.

19. The method of claim 18 wherein the chalcogenide comprises a GST material.

20. The method of claim 19 wherein the GST material comprises Ge₂Sb₂Te₅.

21. The method of claim 1 wherein the phase change material comprises silicon.

22. A nonvolatile memory cell comprising:
a bottom conductor;
a top conductor;
a dielectric layer having a low-resistance ruptured region therethrough; and
a layer of phase change material, wherein the layer of phase change material is in thermal contact with the dielectric layer,
wherein the dielectric layer and the layer of phase change material are disposed between the bottom conductor and the top conductor, and
wherein the dielectric layer and the layer of phase change material are part of the memory cell.

23. The nonvolatile memory cell of claim 22 wherein the phase change material comprises a chalcogenide.

24. The nonvolatile memory cell of claim 23 wherein the chalcogenide comprises a GST material.

25. The nonvolatile memory cell of claim 24 wherein the GST material comprises Ge₂Sb₂Te₅.

26. The nonvolatile memory cell of claim 22 wherein the phase change material comprises silicon.

27. The nonvolatile memory cell of claim 22 wherein the dielectric layer is a dielectric rupture antifuse.

28. The nonvolatile memory cell of claim 27 wherein the dielectric rupture antifuse comprises an oxide layer or a nitride layer.

29. The nonvolatile memory cell of claim 22 further comprising a non-ohmic conductive device, the non-ohmic conductive device in series with the ruptured region of the dielectric layer and the layer of phase change material.

30. The nonvolatile memory cell of claim 29 wherein the non-ohmic conductive device is a diode.

31. The nonvolatile memory cell of claim 30 wherein the diode is a vertically oriented pillar.

32. The nonvolatile memory cell of claim 29 wherein the non-ohmic conductive device is a MIM device.

33. The nonvolatile memory cell of claim 22 wherein the memory cell is formed above a monocrystalline silicon substrate.

34. The nonvolatile memory cell of claim 22 wherein the memory cell is a memory cell of a monolithic three dimensional memory array.

35. A nonvolatile memory array comprising:
a plurality of substantially parallel, substantially coplanar first conductors formed at a first height above a substrate;
a plurality of substantially parallel, substantially coplanar second conductors formed at a second height, the second height above the first height;
a plurality of first phase change elements disposed between the first and second conductors;
a plurality of first dielectric layers, each first dielectric layer in thermal contact with one of the plurality of first phase change elements, each of the first dielectric layers having a high-conductance ruptured region therethrough; and
a plurality of first memory cells, wherein each memory cell of the plurality comprises a) one of the first phase change elements, b) one of the first dielectric layers, c) a portion of one of the first conductors, and d) a portion of one of the second conductors.

36. The nonvolatile memory array of claim 35 wherein each of the plurality of first phase change elements comprises a chalcogenide material.

37. The nonvolatile memory array of claim 36 wherein the chalcogenide material comprises a GST material.

38. The nonvolatile memory array of claim 35 further comprising a plurality of first non-ohmic conductive devices, wherein each of the first memory cells comprises one of the first non-ohmic conductive devices.

39. The nonvolatile memory array of claim 38 wherein the first non-ohmic conductive devices are first diodes.

40. The nonvolatile memory array of claim 39 wherein the first diodes are semiconductor junction diodes.

41. The nonvolatile memory array of claim 40 wherein the first diodes are vertically oriented pillars.

42. The nonvolatile memory array of claim 35 further comprising a plurality of substantially parallel, substantially coplanar third conductors formed at a third height, the third height above the second height.

43. The nonvolatile memory array of claim 42 further comprising:
a plurality of second phase change elements; and
a plurality of second dielectric layers.

44. The nonvolatile memory array of claim 43 wherein the plurality of second phase change elements and the plurality of second dielectric layers are disposed between the second conductors and the third conductors.

45. The nonvolatile memory array of claim 43 further comprising a plurality of substantially parallel, substantially coplanar fourth conductors formed at a fourth height, the fourth height above the third height.

46. The nonvolatile memory array of claim 45 wherein the plurality of second phase change elements and the plurality of second dielectric layers are disposed between the third conductors and the fourth conductors.

47. The nonvolatile memory array of claim 35 wherein each of the dielectric layers comprises an oxide or a nitride.

48. A monolithic three dimensional memory array comprising:
a) a first memory level, the first memory level comprising:
i) a plurality of substantially coplanar first conductors;
ii) a plurality of substantially coplanar second conductors above the first conductors;
iii) a plurality of first dielectric regions, each having a low-resistance ruptured region therethrough;
iv) a plurality of first phase change elements, each phase change element in series with the ruptured region of one of the first dielectric regions, wherein each of the first dielectric regions and each of the first phase change elements are disposed between one of the first conductors and one of the second conductors; and
b) a second memory level monolithically formed above the first memory level.

49. The monolithic three dimensional memory array of claim 48 wherein each of the first phase change elements comprises chalcogenide material.

50. The monolithic three dimensional memory array of claim 49 wherein the chalcogenide material is a GST material.

51. The monolithic three dimensional memory array of claim 50 wherein the GST material is Ge₂Sb₂Te₅.

52. The monolithic three dimensional memory array of claim 48 wherein the first memory level further comprises a plurality of first non-ohmic conductive elements, each first non-ohmic conductive elements in series with one of the first phase change elements.

53. The monolithic three dimensional memory array of claim 52 wherein the first non-ohmic conductive elements are first diodes.

54. The monolithic three dimensional memory array of claim 53 wherein the first diodes are vertically oriented pillars.

55. The monolithic three dimensional memory array of claim 54 wherein each of the first diodes comprises a semiconductor junction diode.

56. The monolithic three dimensional memory array of claim 48 wherein the dielectric regions comprise an oxide layer or a nitride layer.

57. The monolithic three dimensional memory array of claim 56 wherein the low-resistance ruptured region in each dielectric region was formed by dielectric breakdown of the oxide or nitride layer.

58. A method for forming and programming a plurality of memory cells, the method comprising:
forming a plurality of substantially coplanar first conductors above a substrate;
forming a plurality of substantially coplanar second conductors above the first conductors;
forming a plurality of first dielectric regions;
forming a plurality of first phase change elements, each in thermal contact with one of the first dielectric regions, wherein each of the first phase change elements and each of first dielectric regions are disposed between one of the first conductors and one of the second conductors;
forming a low-resistance ruptured region through each of the first dielectric regions; and
causing a phase change of any of the phase change elements by flowing a current through the low-resistance ruptured region of one of the first dielectric regions.

59. The method of claim 58 wherein the phase change elements comprise a chalcogenide.

60. The method of claim 59 wherein the chalcogenide is a GST material.

61. The method of claim 58 wherein the step of forming a low-resistance ruptured region through each of the first dielectric regions comprises applying a voltage across each first dielectric region sufficient to cause dielectric breakdown.

62. The method of claim 58 wherein the step of causing a phase change of any of the first phase change elements comprises changing the phase change element from a first phase to a second phase.

63. The method of claim 62 wherein the first phase is a low-resistance phase and the second phase is a high-resistance phase.

64. The method of claim 62 wherein the first phase is a high-resistance phase and the second phase is a low-resistance phase.

65. The method of claim 58 further comprising forming a plurality of first non-ohmic conductive elements, each first non-ohmic conductive element disposed between one of the first conductors and one of the second conductors.

66. The method of claim 65 wherein the first non-ohmic conductive elements are first diodes.

67. The method of claim 66 wherein each first diode is in series with one of the first dielectric regions or with one of the first phase change elements.

68. The method of claim 67 further comprising forming a plurality of substantially coplanar third conductors above the second conductors.

69. The method of claim 68 further comprising:
forming a plurality of second dielectric regions; and
forming a plurality of second phase change elements, each in series with one of the second dielectric regions.

70. The method of claim 69 wherein each of the plurality of second dielectric regions and each of the plurality of second phase change regions are disposed between one of the third conductors and one of the second conductors.

71. The method of claim 69 further comprising forming a plurality of substantially coplanar fourth conductors above the third conductors.

72. The method of claim 71 wherein each of the plurality of second dielectric regions and each of the plurality of second phase change regions are disposed between one of the third conductors and one of the fourth conductors.

73. A method for forming and programming a nonvolatile memory cell, the method comprising:
forming a layer of phase change material;
forming a heater layer;
forming a dielectric layer disposed between the layer of phase change material and the heater layer and in contact with both; and
forming a low-resistance rupture region through the dielectric layer.

74. The method of claim 73 wherein the step of forming a low-resistance rupture region through the dielectric layer comprises applying a breakdown voltage across the dielectric layer sufficient to cause dielectric breakdown of the dielectric layer.

75. The method of claim 73 further comprising programming the memory cell wherein, during programming, a programming current flows through the low-resistance rupture region.

76. The method of claim 75 wherein the step of programming the memory cell comprises converting the phase change material from a first state to a second state.

77. The method of claim 76 wherein the first state is a low-resistance state and the second state is a high-resistance state.

78. The method of claim 76 wherein the first state is a high-resistance state and the second state is a low-resistance state.

79. The method of claim 76 wherein, after programming, the memory cell can be returned to the first state.

80. The method of claim 75 further comprising forming a non-ohmic conductive element, wherein, during the programming step, the programming current flows through the non-ohmic conductive element.

81. The method of claim 80 wherein the non-ohmic conductive element is a diode.

82. The method of claim 81 wherein the diode is in electrical contact with the dielectric layer.

83. The method of claim 81 wherein the diode is a semiconductor junction diode.

84. The method of claim 83 wherein the step of forming the dielectric layer comprises forming an oxide or nitride layer.

85. The method of claim 73 wherein the phase change material comprises a chalcogenide.

86. The method of claim 85 wherein the chalcogenide comprises a GST material.

87. The method of claim 73 wherein the heater layer comprises a metal silicide.

88. The method of claim 73 wherein the heater layer comprises titanium nitride.

89. A nonvolatile memory cell comprising:
a bottom conductor;
a top conductor;
a dielectric layer having a low-resistance ruptured region therethrough;
a layer of phase change material; and
a heater layer;
wherein the dielectric layer is disposed between and in contact with the layer of phase change material and the heater layer, and
wherein the dielectric layer and the layer of phase change material are disposed between the bottom conductor and the top conductor, and wherein the dielectric layer and the layer of phase change material are part of the memory cell.

90. The nonvolatile memory cell of claim 89 wherein the phase change material comprises a chalcogenide.

91. The nonvolatile memory cell of claim 90 wherein the chalcogenide comprises a GST material.

92. The nonvolatile memory cell of claim 89 wherein the dielectric layer is a dielectric rupture antifuse.

93. The nonvolatile memory cell of claim 92 wherein the dielectric rupture antifuse comprises an oxide layer or a nitride layer.

94. The nonvolatile memory cell of claim 89 further comprising a non-ohmic conductive device, the non-ohmic conductive device in series with the ruptured region of the dielectric layer and the layer of phase change material.

95. The nonvolatile memory cell of claim 94 wherein the non-ohmic conductive device is a semiconductor junction diode.

96. The nonvolatile memory cell of claim 89 wherein the memory cell is a memory cell of a monolithic three dimensional memory array.
